(19) United States
(12) Patent Application Publication
(10) Pub. No.: US 2026/0182236 A1
(43) Pub. Date: Jun. 25, 2026

(54) ANTISOLVENT-MEDIATED AIR QUENCH FOR HIGH EFFICIENCY AIR-PROCESSED CARBON-BASED PLANAR PEROVSKITE SOLAR CELLS

(71) Applicants: Feng YAN, Chandler, AZ (US); Jacob WALL, Tempe, AZ (US)

(72) Inventors: Feng YAN, Chandler, AZ (US); Jacob WALL, Tempe, AZ (US)

(73) Assignee: Arizona Board of Regents on Behalf of Arizona State University, Scottsdale, AZ (US)

(21) Appl. No.: 19/420,624

(22) Filed: Dec. 15, 2025

Related U.S. Application Data
(60) Provisional application No. 63/736,478, filed on Dec. 19, 2024.

(51) Int. Cl. H10K 71/13; H10K 30/40; H10K 30/50; H10K 71/40; H10K 85/50

(52) U.S. Cl. CPC H10K 71/13; H10K 30/40; H10K 30/50; H10K 71/40; H10K 85/50

(57) ABSTRACT

Methods for forming a perovskite solar cell include providing a transparent conductive oxide coated substrate, disposing an electron transport layer (ETL) over the substrate, disposing a volume of a perovskite precursor ink over the ETL, rotating the substrate and disposing a gas mixture, comprising dry air and antisolvent vapor, over the perovskite precursor ink. The method further comprises annealing the substrate to form a perovskite layer, forming a hole transport layer (HTL) over the perovskite layer and forming a substrate over the HTL. Disclosed is a perovskite solar cell including a perovskite photovoltaic layer comprising all, or substantially all, of the photo active α phase and providing a power conversion efficiency exceeding 20%.

### RELATED APPLICATIONS

This application claims the benefit of U.S. provisional patent application 63/736,478, filed Dec. 19, 2024, to Yan et al., titled “ANTISOLVENT-MEDIATED AIR QUENCH FOR HIGH EFFICIENCY AIR-PROCESSED CARBON-BASED PLANAR PEROVSKITE SOLAR CELLS,” the entirety of the disclosure of which is hereby incorporated by this reference.

### STATEMENT REGARDING FEDERALLY SPONSORED RESEARCH OR DEVELOPMENT

This invention was made with government support under 2329871 awarded by the National Science Foundation. The government has certain rights in the invention.

### TECHNICAL FIELD

This document relates generally to materials and methods of manufacture for solar electrical power generation, and specifically to methods for the fabrication of perovskite solar cells formed using quenching methods involving antisolvents and air.

### BACKGROUND

Solar energy represents one of the most affordable and abundant energy sources in the world. However, converting solar energy into electricity significantly relies on the power conversion efficiency of the solar cell technology. Perovskite solar cells (PSCs) have been rigorously researched and pursued as a potential low-cost, next-generation thin-film photovoltaic technology. PSCs have now achieved certified power conversion efficiencies (PCEs) exceeding 26%, which may pave the way to commercial upscale manufacturing. However, the commercialization of PSCs has been hindered due to perovskite instabilities associated with the sensitivity to fabrication under ambient conditions, and fast ion, halide mitigation during typical operating conditions for solar cells.

One approach to improve the stability of PSCs is to replace the costly noble metal electrodes (i.e. Au or Ag) with carbon-based electrodes. In so doing, hydrophobic carbon materials may repel moisture and slow down halide ion mitigation. However, carbon electrodes are not as conductive as the noble metals, such as Au and Ag, which results in a power conversion efficiency PCE of ˜22% (PCE, the percentage of light power that a solar cell converts into usable electrical power, calculated as Pₒᵤₜ/Pᵢₙ) for the best performing carbon-electrode based PSCs (C-PSCs). Some of the best performing C-PSCs produce a PCE of about 4-5% lower than that of Au-electrode based PSCs (Au-PSCs). In addition, most of the highly efficient perovskite solar cells are processed in controlled environments such as a dry, noble gas ambient, e.g., dry N2 having high purity, which is expensive and hinders the large area manufacturing of perovskite solar modules and realization of the cost benefits derived therefrom.

Ambient air conditions are especially difficult for fabricating PSCs because metal-halide perovskites are notoriously sensitive to moisture levels in the air. Though some reports have indicated that a small amount of water in precursor solutions may be beneficial for the surface morphology and crystallization of perovskite films, ambient processing in humid environments (such as for example having a relative humidity (RH)>30%) has proven to be difficult for formation of viable PSCs. Perovskite films deposited in such high relative humidity environments exhibit incomplete and rapid nucleation, which causes the resulting films to have poor surface morphology, reduced grain size, and overall reduced device performance. Precise control over crystallization kinetics during perovskite film growth may be important in producing efficient and stable PSCs, in particular when processing in air environments.

Thus, the use of numerous additives, new solvents, or interfacial engineering have been introduced to combat moisture-induced instability during ambient processing of PSCs. However, these approaches can be complicated and expensive to reproduce in practicality. Solution processing of the perovskite solar cells may include such techniques as spin coating, antisolvents (ATSs), and gas quenching, which have been developed to accelerate the perovskite solvent vaporization and promote crystallization of perovskite films. However, these methods of solution processing have drawbacks. ATS methods are not readily extended to large-area perovskite film coating, such as blade coating and slot die coating. More recently, gas quenching during blade coating has become popular using a gas knife, however, careful tuning of the gas conditions is necessary. Oftentimes this technique leads to uniformity issues, such as unacceptable variations in thickness, across the perovskite films.

### SUMMARY

In some embodiments, method of making a perovskite solar cell includes: disposing a volume of a perovskite precursor ink over a substrate; disposing a nozzle over the substrate at a distance; rotating the substrate at a first revolution per minute (RPM) for a first duration; disposing a gas mixture, comprising dry air and antisolvent vapor, through the nozzle and over the perovskite precursor ink; and annealing the substrate at a first temperature of from about 100° C. to about 150° C. for an annealing duration of from 5 minutes to 45 minutes to form a perovskite layer comprising the photo active α phase. The method of making a perovskite solar cell includes disposing the gas mixture comprises displacing ambient air with the dry air and antisolvent vapor gas mixture over a surface of the substrate comprising the perovskite precursor ink. The method of making a perovskite solar cell includes annealing the substrate fully converts the perovskite layer from an intermediate phase and the δ phase, present after quenching, to the photo active, a phase.

The method of making a perovskite solar cell includes the antisolvent vapor being formed by passing dry air through an antisolvent bath. In certain implementations, the antisolvent bath comprises any of chlorobenzene, IPA, DEE, toluene and ethanol. In other implementations, the gas mixture comprises the antisolvent vapor in an amount of about 1% to 5%. In various implementations, disposing the gas mixture, comprising dry air and antisolvent vapor, reduces defects in the perovskite film. In some implementations, dry air is disposed prior to disposing the gas mixture.

In some embodiments, a perovskite solar cell includes: a transparent conductive oxide (TCO) coated substrate; an electron transport layer (ETL) disposed over the substrate; a perovskite photovoltaic layer coupled to the ETL, wherein the perovskite photovoltaic layer comprises all, or substantially all, of the photo active, α perovskite phase; a hole transport layer (HTL) coupled to the perovskite photovoltaic layer; and a carbon-based electrode disposed over the HTL. In some embodiments, the cell comprises a PCE exceeding 20%. In various embodiments, the perovskite solar cell retains about 80% of its initial PCE value after at least 35 hours of exposure at 25° C. and 15% relative humidity.

In some embodiments, a method of making a perovskite solar cell includes: disposing a volume of a perovskite precursor ink over a substrate; disposing a gas mixture, comprising dry air and antisolvent vapor, over the perovskite precursor ink; and annealing the substrate at a first temperature for an annealing duration to form a perovskite layer comprising the photo active α phase. In some embodiments, the gas mixture comprises the antisolvent vapor in an amount of about 1% to 5%. In certain embodiments, the first temperature is from about 100° C. to about 150° C. and the annealing duration is from 5 minutes to 45 minutes. In various embodiments, the antisolvent vapor is formed by passing dry air through an antisolvent bath. In numerous embodiments, the antisolvent bath comprises any of chlorobenzene, IPA, DEE, toluene and ethanol. In some embodiments, method of making a perovskite solar cell further includes: disposing a nozzle over the substrate at a distance of 10 mm or higher; and rotating the substrate at a first revolution per minute (RPM) of about 1000 RPM to 7000 RPM for a first duration, the first duration lasting 5 to 60 seconds, wherein the gas mixture is disposed at a pressure of at least 20 psi with a flow rate of at least 5 sccm. In certain embodiments, disposing the gas mixture while rotating the substrate comprises displacing ambient air with the dry air and antisolvent vapor gas mixture over a surface of the substrate comprising the perovskite precursor ink. In some embodiments, annealing the substrate converts the perovskite layer from an intermediate phase and the δ phase, present after quenching, to the photo active, a phase, with at least 95% converting into the α phase. In various embodiments, the dry air is disposed prior to disposing the gas mixture, the dry air having a relative humidity below 5%.

The foregoing and other aspects, features, and advantages will be apparent from the DESCRIPTION and DRAWINGS, and from the CLAIMS if any are included.

### BRIEF DESCRIPTION OF THE DRAWINGS

Implementations will hereinafter be described in conjunction with the appended and/or included DRAWINGS.

FIG. 1A illustrates an embodiment of a perovskite solar cell.

FIGS. 1B & 1C illustrate embodiments of quenching methods as disclosed herein.

FIG. 2A shows different setups for the various quenching methods as disclosed herein.

FIG. 2B illustrates crystallization mechanisms of perovskite thin films as understood through the LaMer model.

FIG. 2C shows a schematic of the stages of perovskite nucleation and growth based on the different evaporation stages that result from the quenching methods shown in FIG. 2B.

FIG. 2D depicts various spin-coated antisolvent chlorobenzene (CB) and air-quenched perovskite films after quench and after anneal.

FIG. 2E shows SEM results for the as deposited films.

FIG. 2F depicts statistical analysis of the grain sizes of the films

FIGS. 3A-3C illustrate X-ray diffraction results of perovskite films formed according to the disclosed method and comparison methods.

FIGS. 4A-4C depict 2D Grazing Incidence Wide-Angle X-ray Scattering (GIWAXS) patterns of perovskite films based on the CB, air, and air+CB quench methods.

FIGS. 5A-5F are graphical illustrations showing the retained intermediate phase, 8 phase and a phase present from films formed using the different quench methods after quench, and after anneal.

FIGS. 6A-6B illustrate results from UV-vis absorption spectra and photoluminescence (PL) measurements on the films prepared with different quench methods.

FIG. 6C shows the time-resolved PL (TRPL) spectra of the perovskite films on glass deposited using the different quench methods as disclosed.

FIG. 7 shows an embodiment of the perovskite solar cell formed according to the disclosed methods.

FIG. 8A illustrates current density-voltage (J-V) curves of PVSK cells according to the embodiment of FIG. 7.

FIG. 8B depicts External quantum efficiency (EQE) measurements for the CB, air, and air+CB-quenched PSCs.

FIGS. 9A-9C illustrates electrical characterization of the devices comprising perovskite films prepared according to the methods disclosed herein.

FIGS. 10A-10C show contact angle measurements on the surface of perovskite films prepared under different quenching conditions.

FIG. 11 depicts MPP test results for the PVSK cell of FIG. 7, as well as results from PVSK cells fabricated using antisolvent quenching (chlorobenzene) alone, and air quenching alone.

### DETAILED DESCRIPTION

Detailed aspects and applications of the disclosure are described below in the following drawings and detailed description of the technology. Unless specifically noted, it is intended that the words and phrases in the specification and the claims be given their plain, ordinary, and accustomed meaning to those of ordinary skill in the applicable arts.

In the following description, and for the purposes of explanation, numerous specific details are set forth in order to provide a thorough understanding of the various aspects of the disclosure. It will be understood, however, by those skilled in the relevant arts, that embodiments of the technology disclosed herein may be practiced without these specific details. It should be noted that there are many different and alternative configurations, devices and technologies to which the disclosed technologies may be applied. The full scope of the technology disclosed herein is not limited to the examples that are described below.

The singular forms “a,” “an,” and “the” include plural referents unless the context clearly dictates otherwise. Thus, for example, reference to “a step” includes reference to one or more of such steps.

The word “exemplary,” “example,” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented, but have been omitted for purposes of brevity.

When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

Throughout the description and claims of this specification, the words “comprise” and “contain” and variations of the words, for example “comprising” and “comprises”, mean “including but not limited to”, and are not intended to (and do not) exclude other components.

As required, detailed embodiments of the present disclosure are included herein. It is to be understood that the disclosed embodiments are merely exemplary of the invention that may be embodied in various forms. Therefore, specific structural and functional details disclosed herein are not to be interpreted as limits, but merely as a basis for teaching one skilled in the art to employ the present invention. The specific examples below will enable the disclosure to be better understood. However, they are given merely by way of guidance and do not imply any limitation.

The present disclosure may be understood more readily by reference to the following detailed description taken in connection with the accompanying figures and examples, which form a part of this disclosure. It is to be understood that this disclosure is not limited to the specific materials, devices, methods, applications, conditions, or parameters described and/or shown herein, and that the terminology used herein is for the purpose of describing particular embodiments by way of example only and is not intended to be limiting of the claimed inventions. The term “plurality”, as used herein, means more than one.

Solar energy represents one of the most affordable and abundant energy sources in the world. However, converting solar energy into electricity significantly relies on the power conversion efficiency of the solar cell technology. Perovskite solar cells (PSCs) have been rigorously researched and pursued as a potential low-cost, next-generation thin-film photovoltaic technology. PSCs have now achieved certified power conversion efficiencies (PCEs) exceeding 26%, which may pave the way to commercial upscale manufacturing. However, the commercialization of PSCs has been hindered due to perovskite instabilities associated with the sensitivity to fabrication under ambient conditions, and fast ion, halide mitigation during typical operating conditions for solar cells.

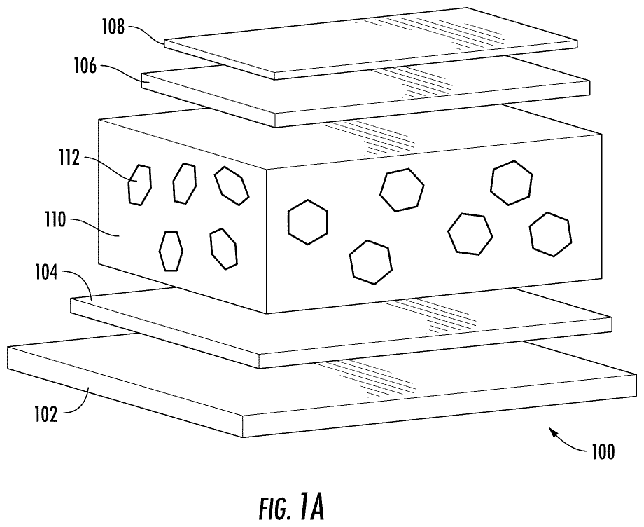

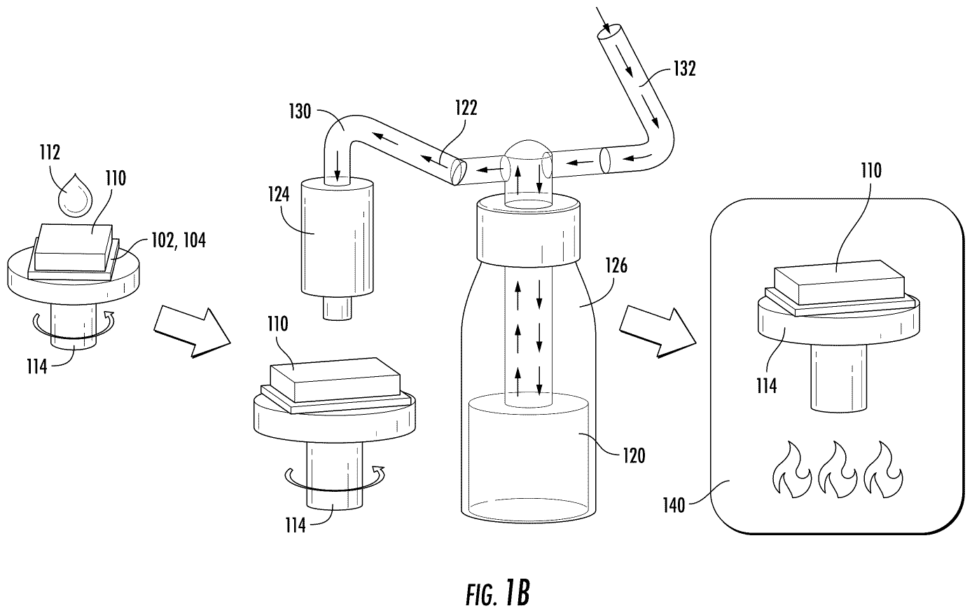

Referring to FIGS. 1A-1C, shown is an exemplary perovskite solar cell (PSC) 100 or device stack which may be fabricated using the antisolvent-mediated, air-quench methods as disclosed herein (e.g., the antisolvent-mediated air-quench method 150 described in FIG. 1C and throughout this disclosure). However, the disclosed antisolvent-mediated air-quench methods 150 and 160 described herein are not limited to a particular perovskite device implementation or a particular device stack (e.g., including perovskite solar cells and perovskite solar device stacks including perovskite solar cell 100 and others known to those of ordinary skill in the art). Rather, the disclosed methods may be applied across a wide range of implementations and device stacks. Broadly, the exemplary perovskite solar cell 100 of FIG. 1A illustrates (from bottom to top): an electrode/substrate layer 102 coupled to an electron transport layer (ETL) 104; a light absorbing, perovskite layer 110 comprising a perovskite photovoltaic material formed from a perovskite precursor solution 112 that was deposited over the ETL 104; a hole transport layer (HTL) 106 coupled to the perovskite layer 110; and an electrode 108 disposed over the HTL 106. For ease of illustration, the perovskite solar cell 100 of FIG. 1A is depicted with different layers spaced apart and floating even though a person of ordinary skill in the art will understand that the deposition of each layer results in adjacent layers touching each other (e.g., perovskite layer 110 is sandwiched between and coupled to ETL 104 and HTL 106, and so forth). The antisolvent-mediated, air-quench methods as disclosed herein (e.g., antisolvent-mediated air-quench method 150) may be applied to devices having PIN or NIP device stacks, as well as other device stacks, without limitation. As a reminder, “NIP” is an inversion of the “PIN” device where PIN devices are stacked as: P: Hole Transport Layer (HTL), I: Intrinsic Layer (Perovskite absorber), and N: Electron Transport Layer (ETL). It follows that a NIP device is stacked as: N: Electron Transport Layer (ETL), I: Intrinsic Layer (Perovskite absorber), and then P: Hole Transport Layer (HTL). Either PIN or NIP devices can be implemented interchangeably with antisolvent-mediated air-quench method 150.

One approach to improve the stability of PSCs is to replace the costly noble metal electrodes (i.e. Au or Ag) with carbon-based electrodes. In so doing, hydrophobic carbon materials may repel moisture and slow down halide ion mitigation. However, carbon electrodes are not as conductive as the noble metals, such as Au and Ag, which results in a power conversion efficiency PCE of ˜22% (PCE, the percentage of light power that a solar cell converts into usable electrical power, calculated as Pₒᵤₜ/Pᵢₙ) for the best performing carbon-electrode based PSCs (C-PSCs). Some of the best performing C-PSCs produce a PCE of about 4-5% lower than that of Au-electrode based PSCs (Au-PSCs). In addition, most of the highly efficient perovskite solar cells are processed in controlled environments such as a dry, noble gas ambient (e.g., dry N₂ having high purity), which is expensive and hinders the large area manufacturing of perovskite solar modules and realization of the cost benefits derived therefrom. Therefore, manufacturing of PSCs in normal, ambient air conditions is important to ensure the scalability, and commercial viability, of the technology.

Ambient air conditions are especially difficult for fabricating PSCs because metal-halide perovskites are notoriously sensitive to moisture levels in the air. Though some reports have indicated that a small amount of water in precursor solutions may be beneficial for the surface morphology and crystallization of perovskite films, ambient processing in humid environments (such as for example having a relative humidity (RH)>30%) has proven to be difficult for formation of viable PSCs. Perovskite films deposited in such high relative humidity environments exhibit incomplete and rapid nucleation, which causes the resulting films to have poor surface morphology, reduced grain size, and overall reduced device performance. Precise control over crystallization kinetics during perovskite film growth may be important in producing efficient and stable PSCs, in particular when processing in air environments.

Thus, the use of numerous additives, new solvents, or interfacial engineering can be added to combat moisture-induced instability during ambient processing of PSCs. However, these approaches can be complicated and expensive to reproduce in practicality. Solution processing of the perovskite solar cells may include such techniques as spin coating, antisolvents (ATSs), and gas quenching, which can accelerate the perovskite solvent vaporization and promote crystallization of perovskite films. However, these methods of solution processing have drawbacks. ATS methods are not readily extended to large-area perovskite film coating, such as blade coating and slot die coating. Gas quenching during blade coating using a gas knife is an option where careful tuning of the gas conditions helps yield better results. Oftentimes, however, this gas quenching with a gas knife technique leads to uniformity issues, such as unacceptable variations in thickness, across the perovskite films. Therefore, a more efficient gas quench approach to promote the perovskite film with more uniformity and fast, controlled crystallization kinetics is needed.

In various embodiments, forming a perovskite solar cell 100 using the antisolvent-mediated air-quench method 150 includes preparing a substrate 152 where substrate 102 may be doped or otherwise prepared for substrate 102 to operate as an electrode in the stack of PSC 100. To build the electron transport layer ETL 104, the ETL 104 is formed, grown, or deposited 154 on the substrate 102. A precursor perovskite material 112 is deposited 156 onto ETL 104 where chuck 114 spins and perovskite film layer 110 is formed from precursor 112 (see, e.g., FIG. 1B, left side). A quenching gas mixture 130 is applied 158 to the perovskite film layer 110, where the quenching gas mixture 130 includes dry air 132 and vapor of ATS solution 120. For example, quenching gas mixture 130 may be formed by passing dry air 132 through ATS solution 120 housed in container 126. The dry air 132 passing through the bath of ATS solution 120 forms an ATS vapor 122 traveling with dry air 132 to form quenching gas mixture 130, which is applied 158 via nozzle 124 to perovskite film layer 110 of PSC 100. Chuck 114 may spin PSC 100 while quenching gas mixture 130 is applied 158 to the perovskite film layer 110. The perovskite film layer 110 undergoes solvent evaporation and phase transformation beginning with the quenching process 158 through the anneal process 162. The anneal process 162 may be conducted in an annealing chamber 140, by heating chuck 114, or a variety of different heating and annealing methods. Once the perovskite film layer 110 has annealed 162 and undergone phase change, a hole transport layer HTL 106 is formed, grown, or deposited 166 on perovskite film layer 110. An electrode 108 is formed 168 and electrically coupled to HTL 106.

While FIG. 1C depicts a non-exclusive example of using antisolvent-mediated air-quench method 150 to form PSC 100 as a NIP device stack, quench method 150 can also form PSC 100 in a PIN device stack. For example, swapping deposit ETL 154 and deposit HTL 166 steps around quenching steps 160 (e.g., FIG. 1B) would build PSC 100 as a PIN device stack instead of a NIP device stack. This disclosure is not limited to perovskite solar cells 100 stacked laminarly as described in examples of some embodiments. In various embodiments, the disclosed ATS air-quenching method 150 can be formed on topographical formations and optionally include additional layers to the device stack of PSC 100.

This disclosure describes various embodiments of air processable methods to manufacture perovskite-based solar cells (e.g., PSC 100) utilizing a combinational gas-quenching technique mediated by antisolvents (ATS) 120 (e.g., antisolvent-mediated air-quench method 150). The antisolvents 120 are added to air (e.g., dry air gas 132) to cause rapid precipitation of a perovskite precursor solution 112 into uniform, compact crystalline films (e.g., perovskite film layer 110) with low defect rates. By incorporating antisolvent vapor 122 (e.g., chlorobenzene) into the gentle air quench process (e.g., method 150), moisture-induced instability has been successfully mitigated, achieving enhanced PSC 100 device performance and stability. Using a combinational quenching method 150 comprising antisolvent vapor 122 added to air quench gas 132 to form quenching gas mixture 130, PCEs exceeding 20% have been obtained, with robust stability against moisture and heat, retaining 80% of their initial efficiency after prolonged exposure without encapsulation. This antisolvent-mediated air-quench method 150 represents a significant advancement towards scalable, air processed solar cells (e.g., PSCs 100) and air processed, carbon electrode-based PSCs (C-PSCs) (e.g., C-PSCs including PSC 100) offering promising opportunities for future large-scale deployment and module development. In various embodiments, PSC 100 includes a carbon electrode and may be referred to as C-PSC 100. The elements used to construct electrode 108 may include carbon (e.g., C-PSC 100) in some embodiments, or electrode 108 may comprise elements and materials other than carbon in other embodiments of PSC 100.

By incorporating antisolvent vapor 122 into the quenching air gas 132, C-PSC films 110 obtain both the benefits of the antisolvent vapor 122 and the dry air quench 132 approach while synergistically providing better than expected results, successfully converting the perovskite film 110 completely, or substantially completely (e.g., at least 80%, at least 90%, at least 95%, at least 98%), from the intermediate phases to the photoactive, a phase and protecting the film 110 from moisture during deposition. Through this innovative approach, C-PSCs 100 can be air processed with enhanced device performance and stability by using antisolvent-mediated air-quench method 150, resulting in a perovskite solar cell 100 having a PCE exceeding 20% while sustaining the improved stability as compared to the single antisolvent, or gas quench, approach.

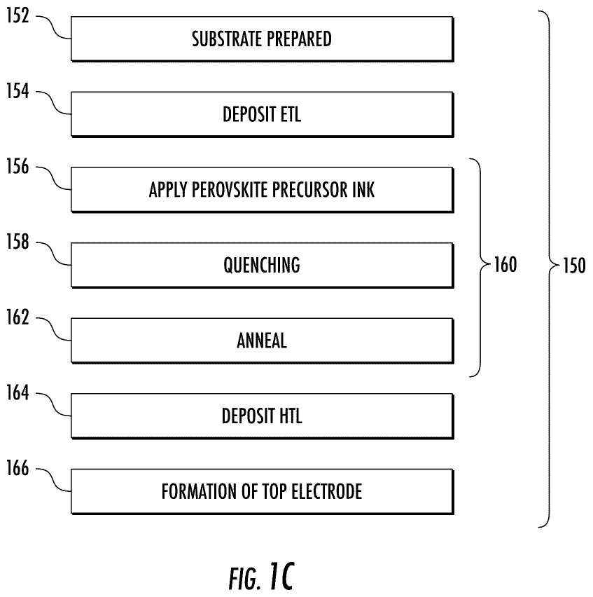

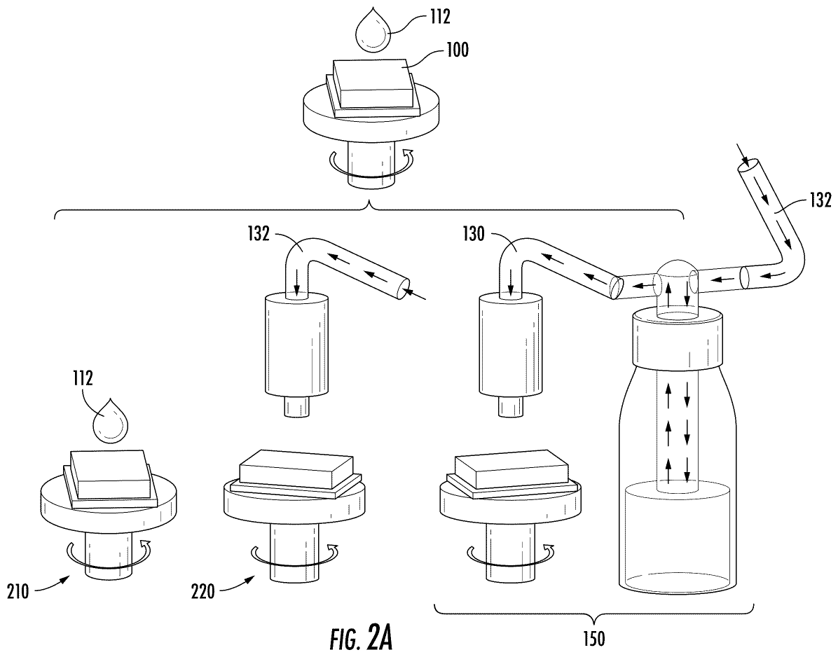

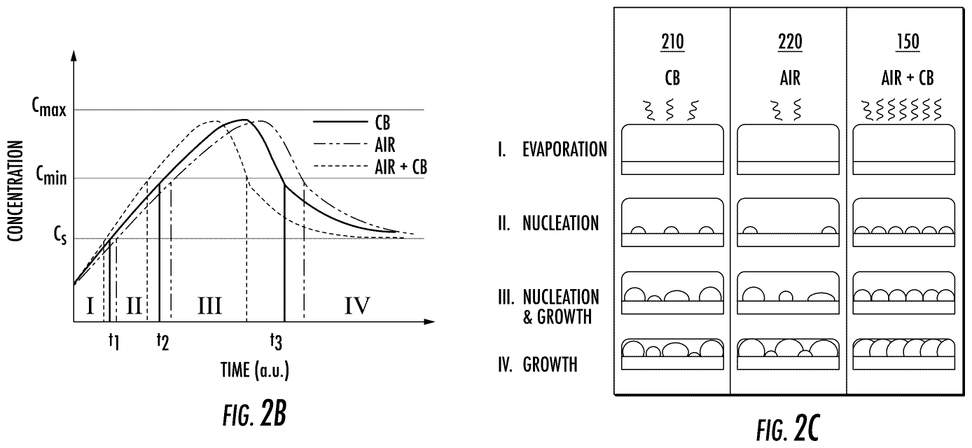

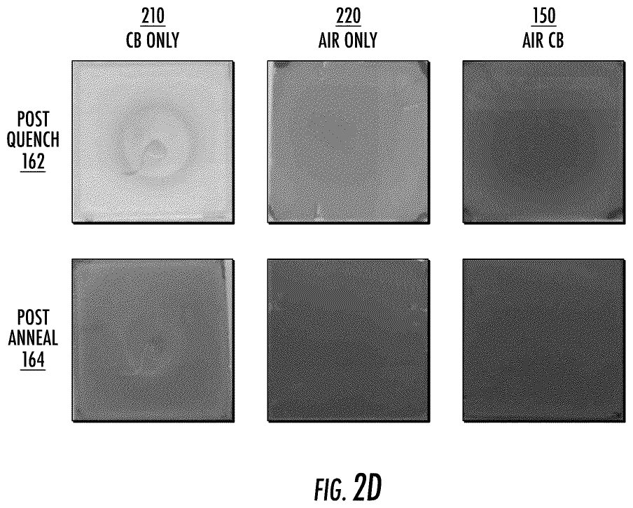

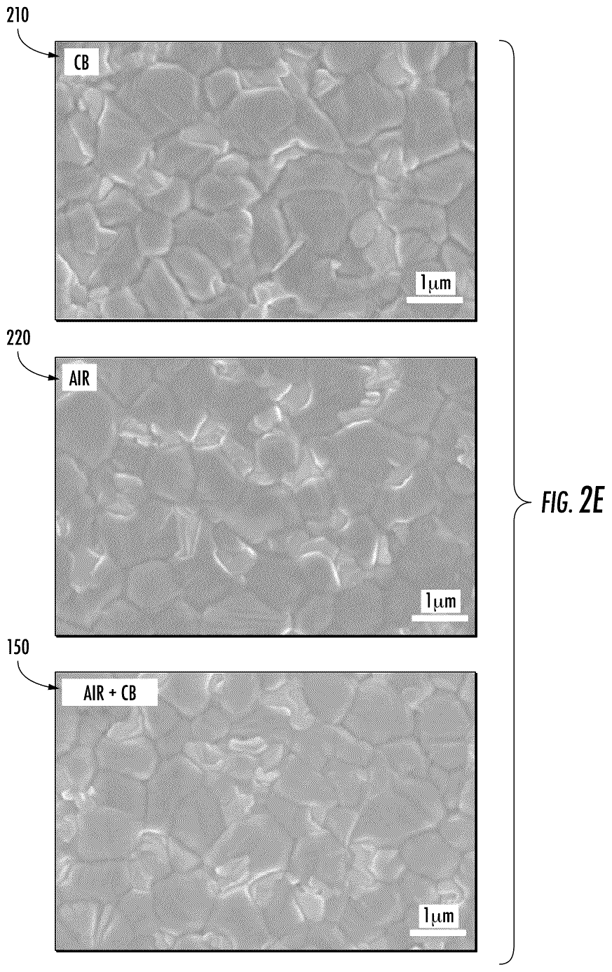

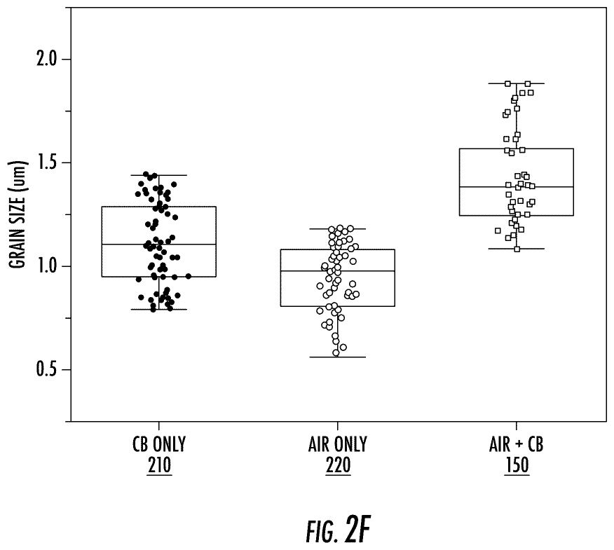

For all figures herein, perovskite films formed using quenching by antisolvent chlorobenzene alone are designated as “CB” 210 films, perovskite films formed using dry air quenching alone without ATS vapor are designated as “Air” 220 films, and perovskite films 110 formed according to the antisolvent-mediated air gas quench methods 150/160 as disclosed herein are designated as “Air+CB” 150 films. As shown in FIG. 2A far right, an antisolvent-mediated air-quenching method 150 utilizing an ATS-modified dry air quenching gas mixture 130 which can provide benefits of both the ATS quenching method 210 and the dry air quenching approach 220 and synergistically providing better than expected results, may be used during the perovskite layer 110 deposition. In numerous embodiments, the perovskite precursor 112 has a composition of CsₓFA_{1-x-y}MA_{y}PbI₃₋ₘBrₘ (X=0 to 0.2, y=0 to 0.1, FA is 1-x-y, m=0 to 0.5) that is deposited 156 on a substrate 102, where FA represents formamidinium and MA refers to methylammonium in this composition. Chlorobenzene (CB) may be used as a representative ATS 120 in this instance, however, other ATS 120 are possible in addition, such as isopropanol (IPA), diethyl ether (DEE), toluene, and ethanol.

The various rates of solvent evaporation directly influence the formation of the perovskite nuclei and subsequently control the transition of the intermediate perovskite phase, i.e., 8-phase, to the photoactive α-phase of the perovskite film 110, after deposition 156. According to the Air+CB method 150 depiction of FIG. 2A as shown on the far right (shown in more detail in FIG. 1B), the dry air gas 132 can be transported through a container 126 holding a bath of ATS solution 120, such as CB, and thereafter the ATS vapor 122, in this instance comprising CB vapor, is carried to a nozzle 124 of a spin coater delivering the quenching gas mixture 130 to the perovskite film 110 comprising precursor 112 during spin coating of the perovskite film 110. Dry air with relative humidity (RH) of about 3% may be used as the dry air 132 component of quenching gas mixture 130, however other RH values are possible for dry air 132 (e.g., RH below: 2%, 1%, 5%, 8%, 10%, and so forth).

FIG. 2B illustrates crystallization mechanisms of perovskite thin films as understood through the LaMer model. Four stages occur during the perovskite film 110 deposition: In stage I, the precursor (e.g., precursor 112) concentration gradually reaches a saturation point (Cs) as the solvent begins to evaporate, and the perovskite precursor ink 112 is spread out evenly on the substrate 102. In stage II, a few initial nuclei form. As the solvent continues to evaporate, the solute content increases as well. Eventually, the solution becomes supersaturated, reaching a minimum concentration for nucleation to begin (Cmin), and nucleation occurs rapidly until the solute is consumed and the concentration drops back below Cmin (stage III). After this point, crystalline growth remains, and it primarily occurs through diffusion processes such as Ostwald ripening. Here, the ATS only approach 210 quickly removes most of the solvent during spin coating, while the pure air gas quench approach 220 may result in slower solvent extraction than that of the ATS only method 210.

Through the novel combination of the CB and air quench approaches according to the disclosed antisolvent-mediated air-quench method 150, solvent evaporation may occur at a moderate rate. The moderate rate may be between the solvent evaporation rate of the conventional ATS approach 210 and the solvent evaporation rate of the pure air gas quench 220, thereby providing a mild rate of perovskite film 110 growth. The perovskite film 110 growth and thickness may be observed by the change in color of the perovskite film 110 after coating, from transparent when thinner to dark brown with increasing thickness. According to embodiments of the disclosed antisolvent-mediated air-quench method 150, the antisolvent vapor 122 (e.g., chlorobenzene vapor 122) may be present in the gas mixture 130 in an amount of from about 1% to about 5%. In some embodiments, the chlorobenzene vapor 122 or other ATS vapor 122 is provided simultaneous with the dry air 132. In further embodiments, dry air 132 may be provided prior to introduction of the ATS vapor 122 (e.g., chlorobenzene vapor 122) and maintained throughout the time the ATS vapor 122 is applied to perovskite film 110.

FIG. 2C shows a schematic of the stages of perovskite nucleation and growth based on the different evaporation stages that result from the quenching methods shown in FIG. 2B. The air+CB quenching method 150 can increase solvent evaporation compared with the CB-only 210 or air-quench 220 process alone. Therefore, the antisolvent-mediated air-quench method 150 promises the formation of a dense and compact perovskite film 110.

As shown in FIG. 2D, the spin-coated CB 210 and air-quenched 220 perovskite films 110 exhibit high transparency and are light in color due to residual solvents of dimethylformamide (DMF) and dimethyl sulfoxide (DMSO). The as-casted air+CB-quenched 150 perovskite films 110 are dark in appearance indicating a phase transformation from the yellow, δ-to the black, α-phase FAPbI3 (where FA represents formamidinium) during the CB-mediated air-quench process 150 as disclosed herein. While the pure air quenched 220 film exhibits a slightly dark appearance than the CB only 210 method, by introducing CB vapor 122 into the quenching gas 132 (i.e., air+CB gas mixture 130), a darker and uniform as-deposited perovskite film 110 is produced, facilitating the subsequent transition to the black, α-phase FAPbI3 upon annealing 162.

SEM results for the as deposited perovskite films 110 are shown in FIG. 2E, and statistical analysis of the grain sizes are depicted in FIG. 2F. Grain sizes for perovskite films 110 formed from the antisolvent-mediated air-quench method 150 (labeled “air+CB) display an average grain size of 1.42 μm, which is larger than that of 1.12 and 0.94 μm for the CB-only 210 and air-only 220 methods, respectively. The increased grain size may be attributed to a faster rate of solvent evaporation and the faster conversion of intermediate phase transitions to the α perovskite phase.

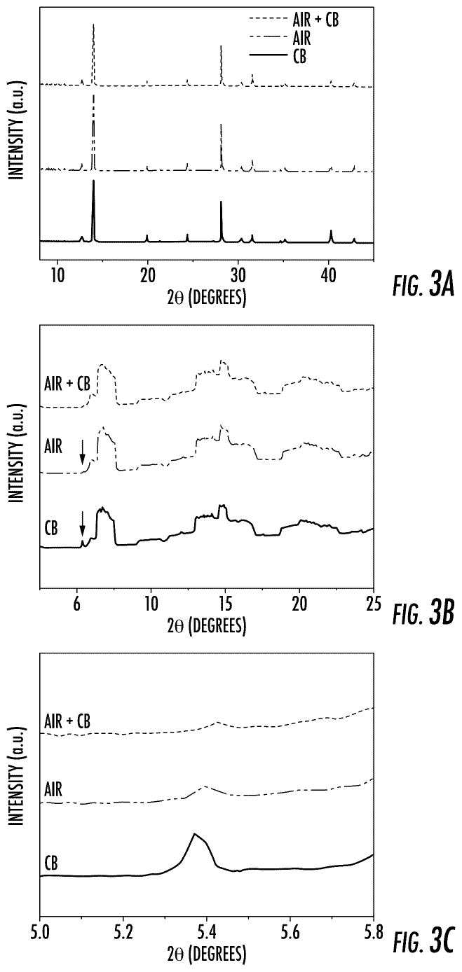

The bulk crystallinity of the perovskite films 110 was characterized using X-ray diffraction (XRD). FIGS. 3A-3C depict X-ray diffraction results showing the structure of the antisolvent-mediated air-quench 150 treated perovskite films 110 compared to the different quenching methods of ATS-only 210 (labeled “CB”) and dry air only 220 (labeled “AIR”). FIG. 3A illustrates x ray diffraction across a wide-angle range of about 8 degrees to 45 degrees, FIG. 3B shows results from low angles of about 2.5 degrees to 25 degrees, illustrating slight peaks in the diffraction pattern corresponding to a PbI2 peak at 2θ≈12.5° due to the excess PbI2 added in the precursor. FIG. 3C shows similar results to FIG. 3B over a further narrowed, low angle range. The XRD results indicate perovskite films 110 formed from the disclosed antisolvent-mediated air-quench method 150 produced the photoactive, cubic a phase. No indication of the presence of the intermediate phase or δ phase are seen for the film formed according to the antisolvent-mediated air-quench method 150 depicted in FIGS. 3B and 3C.

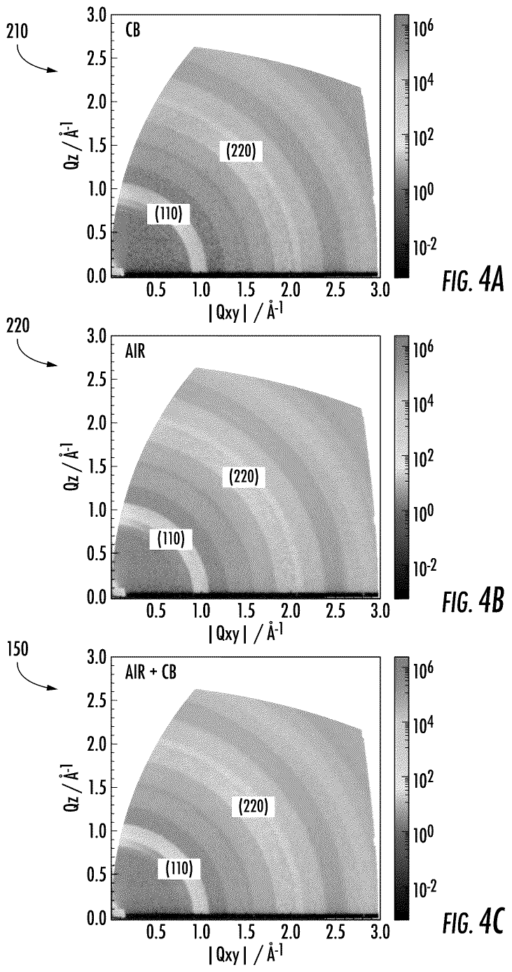

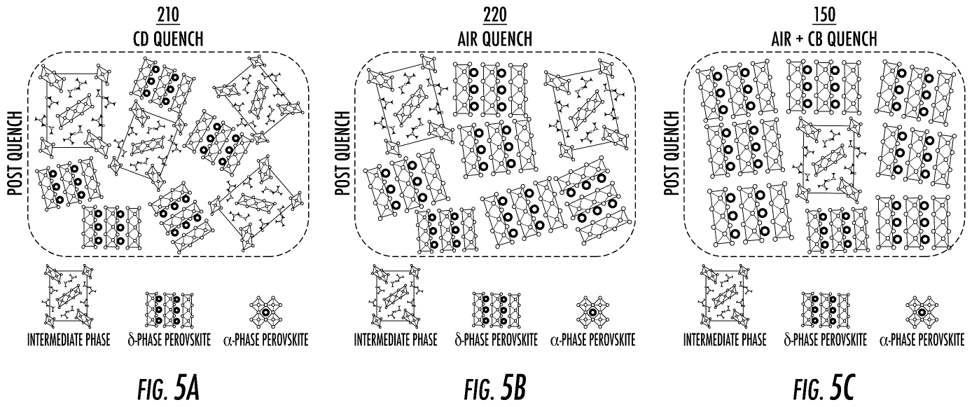

To further characterize the crystallinity at the surface of the perovskite films 110, Grazing Incidence Wide-Angle X-ray Scattering (GIWAXS) was performed at an angle of 0.5° for each of the perovskite films 110 formed according to the CB 210, air 220, and air+CB 150 quenching conditions, as shown in FIGS. 4A-4C. FIGS. 4A-4C depict 2D GIWAXS patterns of perovskite films 110 based on the CB 210, air 220, and air+CB 150 quench methods. All perovskite films 110 show characteristic Bragg rings at q=1.0 and q=2.0 Å⁻¹, which corresponds to the (110) and (220)diffractions of perovskite, respectively. However, when looking at the derived XRD diffraction patterns for the different quenched perovskite films 110, as shown in FIGS. 3B and 3C, low angle peaks at ˜5.4° may be seen, which can be attributed to quasi-2D perovskites or intermediate phases, which may be a result of methylammonium chloride (MACL) or other components present in the precursor inks 112. FIG. 3C shows the presence of the 2D perovskite peak at 5.38° using CB quenching alone 210. Using the combined air+CB method 150 as disclosed herein, the peak is seen as largely eliminated, indicating increased phase purity with the combined air+CB method 150 as disclosed herein. Although the formation of an intermediate phase may be beneficial during crystallization, the retention of this intermediate phase post annealing 162 could restrict charge transfer and reduce the overall device efficiency and PCE results. Thus, a perovskite film 110 having a high degree of phase purity, minimizing the intermediate phase (as shown in the schematics of FIGS. 5A-5F following), is desirable.

FIGS. 5A-5F are graphical illustrations showing the various phases present from perovskite films 110 formed using the different quench methods as disclosed herein, both after quench 158 and after anneal 162. A key showing the following is depicted: an intermediate phase, the δ phase, and the perovskite α phase. As shown in FIGS. 5A and 5B, the CB quench 210 and air quench 220 methods lead to perovskite films 110 having greater amounts of intermediate phases present following quenching 158. As a result, this leads to an incomplete conversion of the intermediate phases to the photoactive, α-phase, upon annealing 162. In contrast, perovskite films 110 formed according to the air+CB quench process 150 as shown in FIG. 5C results in formation of the greatest amount of the δ phase after quenching 158. The presence of the δ phase after quenching 158 leads to complete, or nearly complete, conversion of intermediate phases and the δ phase to the desired α-phase following annealing 162, as shown in FIG. 5F. As shown by comparing FIGS. 5D-5F, perovskite films 110 formed from the air+CB quench methods 150 comprised the highest levels of the desired perovskite α-phase after quenching 158 and annealing 162. Perovskite films 110 formed from the air+CB quench methods 150 resulted in all, or substantially all, of the perovskite δ phase converting to perovskite α-phase upon annealing 162.

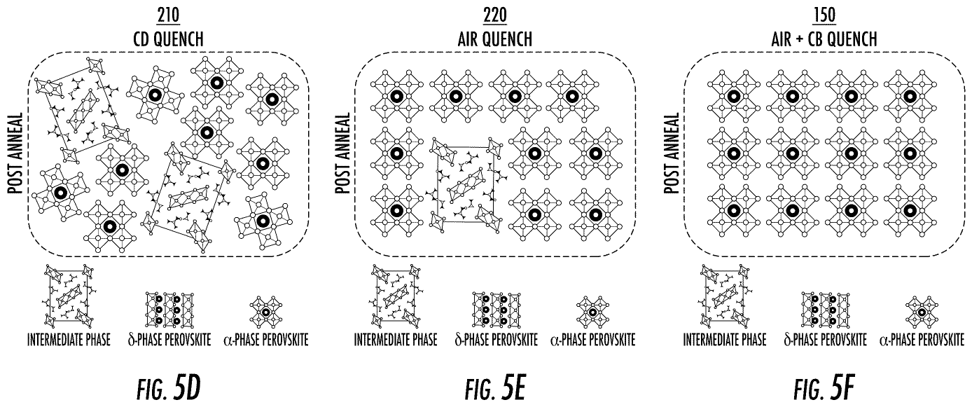

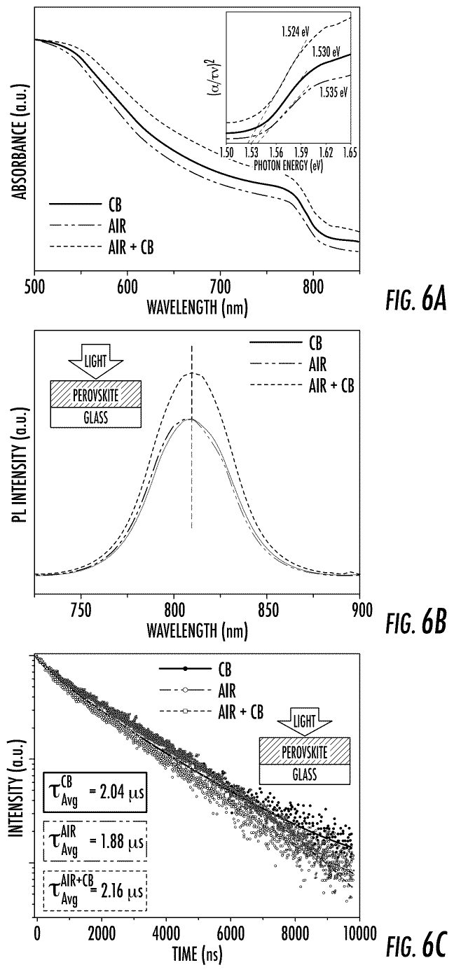

Perovskite films 110 were deposited on bare glass and UV-vis absorption spectra and photoluminescence (PL) measurements were taken of films prepared with the different quench techniques as shown in FIG. 6A. The air+CB-quenched 150 perovskite film 110 displayed enhanced ability for light absorption due to its completed photoactive α-phase transition, when compared to the CB 210 or air-quenched 220 films, which comprised intermediate phases.

Steady-state PL measurements were performed (excited at 643 nm), as shown in FIG. 6B. The air+CB-quenched 150 perovskite film 110 exhibits a stronger PL intensity than those of the CB-only 210 and air-quenched 220 perovskite films. This increased PL intensity indicates that the air+CB 150 perovskite films 110 comprised fewer defects and reduced nonradiative recombination than those quenched with dry air 220 or ATS/CB 210 alone.

FIG. 6C shows the time-resolved PL (TRPL) spectra of the perovskite films 110 on glass deposited using the different quench methods as disclosed. Biexponential fitting (as known in the art) was used to determine the average carrier recombination lifetime. The average carrier recombination lifetimes were found to be 2.04, 1.88, and 2.16 μs for the CB 210, air 220, and air+CB 150 quenched perovskite films 110, respectively. The air+CB-quenched 150 perovskite film 110 exhibits the longest lifetimes, indicating that the removal of the intermediate phase in the final annealing process is critical for the carrier lifetime time, providing a greater chance for collection of the photogenerated carriers during PSC 100 device operation.

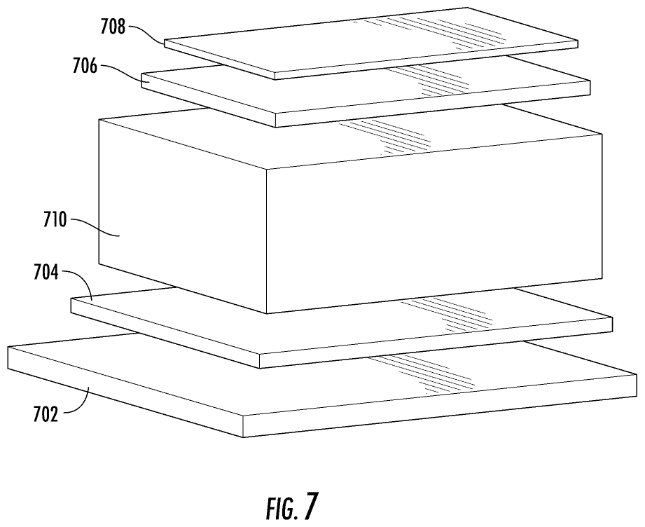

FIG. 7 illustrates an embodiment of a perovskite solar cell 700 created on a substrate 702, where substrate 702 comprises an indium tin oxide (ITO) electrode applied to a glass substrate. Disposed on the ITO-glass substrate 702 is an ETL 704 comprising SnO2, a perovskite layer 710, having a composition of Cs_{0.03}FA_{0.97}PbI_{2.96}Br_{0.04} (where FA represents formamidinium) formed according to the antisolvent-mediated, air gas quench methods 150 as disclosed herein, and an HTL 706 comprising two dimensional Spiro-OMeTAD disposed over the perovskite layer 710. Compositions of CsₓFA_{1-x-y}MA_{y}PbI₃₋ₘBrₘ (X=0 to 0.2, y=0 to 0.1, FA is 1-x-y, m=0 to 0.5), as disclosed earlier herein, are similarly feasible. An electrode 708 is formed on top of HTL 706 in S-PSC 700. According to some embodiments, electrode 708 disposed opposite the ITO electrode/glass substrate 702 and over the Spiro-O-MeTAD HTL 706 may comprise a carbon-based substrate. In some embodiments, the carbon-based substrate of electrode 708 may have a thickness of about 100 μm.

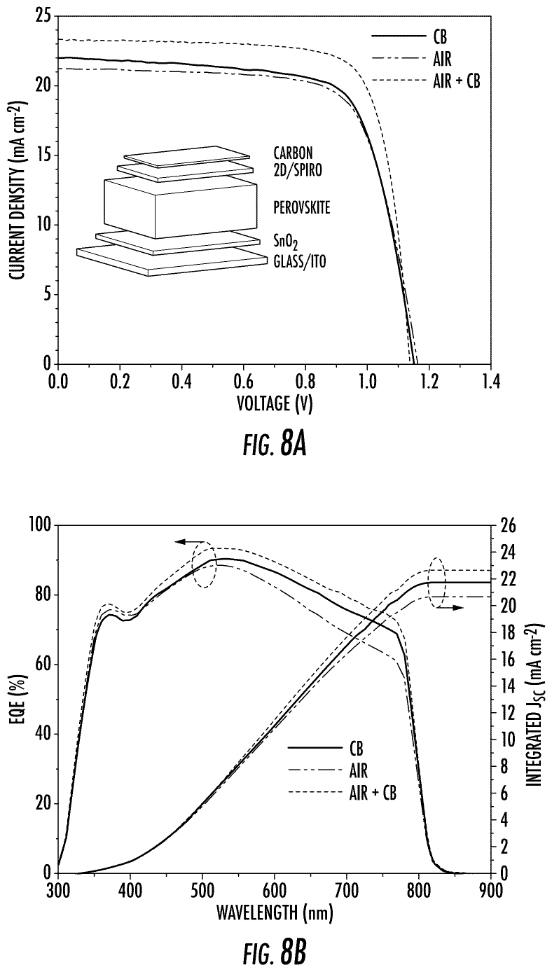

The perovskite solar cell 700 of FIG. 7 was tested using cyclic voltammetry, and the results are depicted in FIG. 8A. FIG. 8A shows the current density-voltage (J-V) curves of PSC 700 devices (area 0.08 cm²) prepared using the different quench techniques for the PSC 700 of FIG. 7. Perovskite films 710 formed from the method using the combined air+CB quench method 150 provided a PCE of greater than 20%, measured as 20.31%, exceeding the PCE of PSC 700 fabricated using antisolvent quenching 210 (chlorobenzene), or air quenching 220 alone (18% and 17.59%, respectively). Table 1 lists statistical device performance for the 15 best PSC 700 cells fabricated using antisolvent quenching 210 (chlorobenzene), air quenching 220, and the combined air and antisolvent quenching 150.

TABLE 1

| | | J_{SC} | Fill | |
|---|---|---|---|---|
| Device | V_{OC} [V] | [mA cm⁻²] | Factor [%] | PCE [%] |
| CB | 1.15 | 22.04 | 70.97 | 18.00 |
| Quench | (1.13 ± 0.020) | (21.26 ± 0..43) | (67.31 ± 2.77) | (16.04 ± 0.89) |
| Air | 1.16 | 21.20 | 71.34 | 17.59 |
| Quench | (1.10 ± 0.010) | (21.67 ± 0.33) | (64.35 ± 3.97) | (15.14 ± 1.39) |
| Air + CB | 1.14 | 23.27 | 76.63 | 20.31 |
| Quench | (1.16 ± 0.017) | (23.51 ± 0.60) | (74.34 ± 2.86) | (18.61 ± 0.84) |

External quantum efficiency (EQE) measurements for the CB 210, air 220, and air+CB 150 quenched PSCs 700 are shown in FIG. 8B. The integrated J_{SC} was found to be 21.78, 20.71, and 22.70 mA cm2 for the CB 210, air 220, and air+CB 150 quenched devices, respectively. The PSC 700 devices comprising perovskite films 710 formed from the air+CB-quenched methods 150 exhibited an improved EQE in the visible light region from 400 to 700 nm compared to the other quenching methods (i.e., CB 210 and air-only 220). This enhancement shows that the incorporation of CB vapor 122 in the air-quenching gas 132 may promote more photons to be converted to electrons for the visible sunlight by reducing charge recombination and enhancing charge extraction processes. Statistical device performance was collected from the best 15 solar cells for each quenching technique. As shown in Table 1, the CB-only quenched 210 devices exhibited an average Voc of 1.13 V, a J_{SC} of 21.26 mA cm2, an FF of 67.31%, and a PCE of 16.04%, and the air-quenched 220 devices exhibited an average Voc of 1.10 V, a J_{SC} of 21.20 mA cm2, an FF of 64.35%, and a PCE of 15.14%. The combined air+CB quenched 150 devices displayed an average Voc of 1.16 V, a J_{SC} of 23.51 mA cm2, an FF of 74.34%, and a PCE of 18.61%. The CB-mediated air-quench method 150 yields significant improvement in all device parameters, leading to an overall improvement in PCE. These results underscore the effectiveness of the combinational gas quenching approach of antisolvent-mediated air-quench method 150 disclosed herein to improve the efficiency of C-PSCs 100 prepared in air processing conditions.

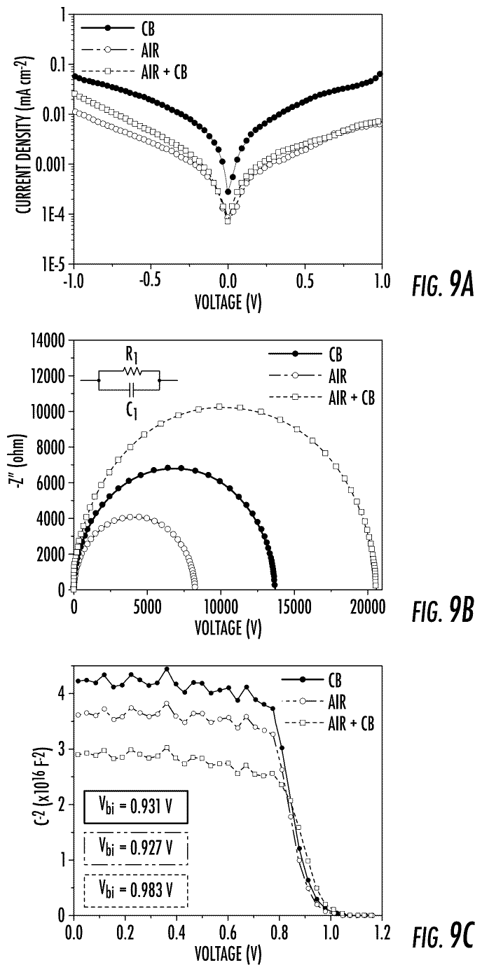

Electrical characterization of the PSC 100/700 devices comprising perovskite films 110 prepared according to the methods disclosed herein are shown in FIGS. 9A-9C. Dark current voltage curves are depicted in FIG. 9A. The dark current density of the air+CB-quenched 150 device is roughly one order of magnitude lower than that of the CB-quenched 210 device, indicating that the air+CB quenching method 150 reduces leakage currents by photogenerated carriers traveling more efficiently through the PSC 100/700 device.

FIG. 9B depicts electrochemical impedance spectroscopy (EIS) results. Nyquist plots derived from EIS were obtained by fitting the equivalent circuit shown in the inset. The low-frequency areas of the Nyquist plot correspond to the charge recombination resistance. As shown in the plot, the air+CB-quenched 150 devices show an enhanced charge recombination resistance, indicating that the addition of CB vapor 122 to the air-quenching medium (e.g., dry air 132) efficiently inhibits charge recombination in PSC 100/700 devices prepared in full air processing environments.

FIG. 9C illustrates Mott-Schottky plots derived from capacitance-voltage (C-V) measurements. According to the plots, the Vbi of the CB 210, air 220, and air+CB 150 quenched devices were found to be 0.931 V, 0.927 V, and 0.983 V, respectively. These results indicate that the combination of air+CB quenching method 150 leads to significant improvement in charge recombination resistance of the ambient-processed C-PSCs 100/700.

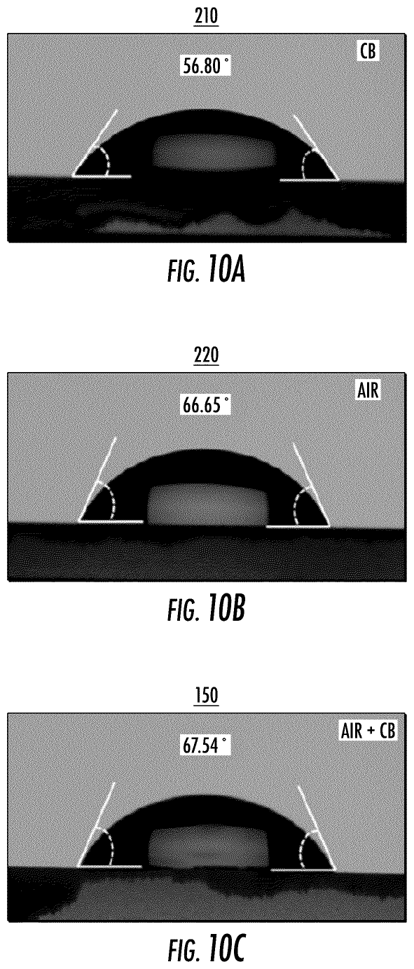

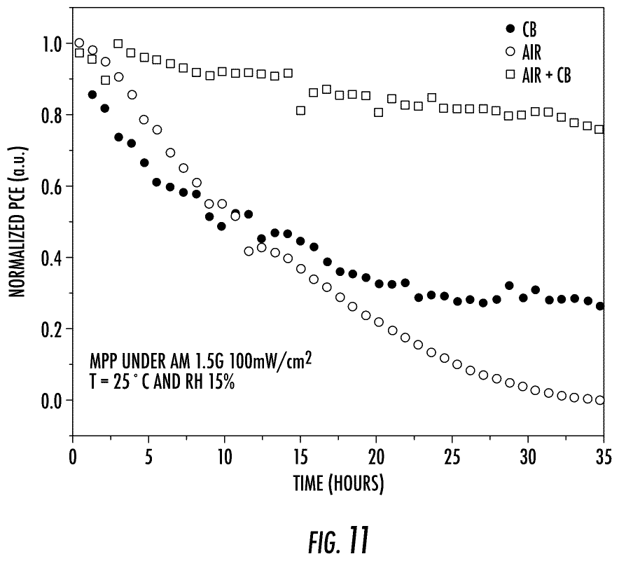

As shown in FIGS. 10A-10C, the contact angle of a static water droplet on the surface of perovskite films prepared under different quenching conditions was measured. FIG. 10A was prepared using the CB-only method 210, FIG. 10B was prepared using the Air-only method 220, and FIG. 10C was prepared using the antisolvent-mediated air-quench method 150. The contact angle increases for the combined air+CB quenching method 150, which may be ascribed to the enhanced grain size pinhole-free surface of these perovskite films 110/710, and the reduced PbI2 residual on the surface as shown in FIG. 3B. Thus, the air+CB method 150 may be more effective at minimizing the infiltration of moisture into the perovskite crystal, protecting the perovskite film 110/710 from degradation and maximizing its long-term stability in humid environments.

Shown in FIG. 11 are maximum power point (MPP) tests performed at a temperature of 25° C. and relative humidity of 15% for the PSCs 100/700 prepared under different quenching conditions. The normalized PCE results are over a 35 hour duration at MPP for the perovskite solar cell 700 of FIG. 7, as well as results from PSC 700 cells fabricated using antisolvent quenching (chlorobenzene) alone 210, and air quenching alone 220. The results are normalized to express the PCE as a percentage of its original PCE value. As depicted by FIG. 11, the PSC 700 cell of FIG. 7, made according to the disclosed method of combined air and antisolvent quenching 150, retained about 80% of its initial PCE value, far greater than the normalized PCE of PSC 700 cells fabricated from antisolvent quenching (chlorobenzene) alone 210 (˜25% at 35 hrs), and air quenching alone 220 (˜0% at 35 hrs), at a temperature of 25° C. and 15% RH, without external encapsulation. The PSC 100/700 cells fabricated from the CB and Air method 150 reached 80% of their initial PCE values at less than 5 hours. This increase in stability illustrates the benefits of the air+CB quenching methods 150 as disclosed herein to improve the robustness and long-term stability of PSCs 100/700.

Referring to the disclosure herein, an antisolvent-mediated air-quench method 150 may be utilized to make perovskite (PVSK) solar cells (e.g., PSC 100, PSC 700). As disclosed herein, the antisolvent-mediated air-quench method 150 may comprise providing or preparing a substrate 152, where a substrate electrode 102/702 is coated with a transparent conductive oxide (TCO) as an electrode. In some embodiments the TCO layer of substrate electrode 102/702 may comprise indium tin oxide (ITO), although other TCO materials may be used. The TCO may be deposited by sputtering, co-sputtering, pulsed laser deposition, sol-gel processes, spin coating, and atomic layer deposition. Other deposition techniques may be used according to product requirements.

The antisolvent-mediated air-quench method 150 further includes disposing an electron transport layer (ETL) 154, where the ETL 104/704 is disposed over the substrate and TCO coating of substrate electrode 102/702. In some embodiments, the ETL 104/704 comprises tin oxide (SnO2), such as an n-type SnO2. The ETL 104/704 may be disposed by solution processing methods, such as by spin coating, spray coating, sol-gel processing, solution casting, drop dry deposition, and sputtering. Other materials, such as TiO2, ZnO, Fullerenes (such as C60, PCBM), Gallium oxides, and Graphene may also be used for the ETL 104/704, and disposed using similar methods.

According to the antisolvent-mediated air-quench methods 150 as disclosed herein, the perovskite layer 110/710 may be formed by disposing a volume of a perovskite precursor ink 156. The perovskite precursor ink 112 is deposited over the ETL 104/704 formed on the substrate 102/702, which is placed on the chuck 114 of a spin coating apparatus. The volume of precursor ink 112 is sufficient to cover a majority of, or the entirety of, the surface of the ETL 104/704 and substrate 102/702. The perovskite precursor ink 112 may comprise solvents, such as dimethylformamide (DMF), dimethyl sulfoxide (DMSO), N-Methyl-2-Pyrrolidone (NMP), and similar solvents that are compatible with the selected antisolvent 120.

Thereafter, the antisolvent-mediated air-quench method 150 includes quenching the perovskite layer 158. A nozzle 124 is disposed over the substrate 102/702 and on top of the spin coating apparatus and chuck 114 at a distance from the substrate 102/702. The distance between the nozzle 124 and a surface of the precursor ink 112 on the substrate 102/702 and ETL 104/704 can vary depending on the conditions present during the precursor ink 112 deposition 156, such as gas pressure and flow rate. Typically, the distance may be from 10 mm to 50 mm, or about 30 mm using a gas pressure of from about 10-30 psi to 70 psi and flow rate of from about 5 standard cubic centimeters per minute (sccm) to 15 sccm, although ranges beyond these may be possible. The nozzle distance, gas pressure, gas flow rate and film coating speed may be interrelated and optimized together as part of the disclosed antisolvent-mediated air-quench method 150. The nozzle 124 may comprise two or more separate ports or openings for two or more gas inputs. Input gases may thereafter combine within the nozzle 124 prior to disposing them over and onto the perovskite precursor ink 112 to quench 158 the perovskite film 110/710. The nozzle 124 may be configured for control of the flowrate and pressure of the input gases (e.g., dry air 132 and ATS vapor 122), as well as combining the gases in a manner such that the resulting perovskite film 110/710 is not damaged during the quenching process 158.

According to embodiments as disclosed herein, the input gases may comprise dry air 132 (where dry air comprises the mixture of all gases present in air, including nitrogen, oxygen, carbon monoxide, and inert gases, except water vapor) and vapor from an antisolvent, such as ATS vapor 122 or CB ATS vapor 122. The dry air 132 used during the quenching process 158 works to minimize the relative humidity (% RH) in the spin-coater by displacing higher moisture content air from within the spin coater during coating, such that the ATS vapor 122 contacts the precursor ink 112 in a low humidity environment, which protects the peovskite film 110/710 from moisture during coating 156 and crystallization, and thereby reduces defects. According to some embodiments, the antisolvent-mediated air-quench method 150 as disclosed herein may be implemented with ambient conditions having a relative humidity of from 0 to 50% RH. The antisolvent vapor 122 may be formed by blowing dry air 132 through a bubbler container 126 enclosing the antisolvent 120 in the form of a liquid. The pressure and flow rate of the dry air 132 sent through the bubbler 126 may also be controlled and adjusted. According to the disclosed method, any antisolvent 120 appropriate for quenching 158 the perovskite film 110/710 can be used, such as chlorobenzene (CB), 2-proponal (IPA), ethanol, toluene, and diethyl-ether (DEE).

Next, the antisolvent-mediated air-quench method 150 comprises using a spin coating process and rotating the substrate 102/702 on the chuck 114 at a first revolution per minute (RPM) for a first duration to initially coat the ETL 104/704 on substrate 102/702 and disperse the precursor ink 112, and rotating the substrate 102/702 at a second RPM for a second duration, where the second RPM is greater than the first RPM. For example, the first RPM may be about 1000 RPM for a duration of about 5 to 30 seconds, or about 20 seconds and the second RPM may be from about 2000 RPM to about 6000 RPM, or about 5000 RPM for from about 20 seconds to about 50 seconds or 60 seconds. In further embodiments, the substrate 102/702 may be subjected to a single rotational process comprising an RPM of from about 2000 RPM to about 6000 RPM for a duration of from about 20 seconds to about 60 seconds. The selection of the RPM, number of rotational processes or variations, and duration as part of the spin coating process may differ dependent upon the perovskite precursor concentration.

After spinning the substrate at the desired RPM for the specified duration, the antisolvent-mediated air-quench method 150 includes disposing the gas mixture 130, comprising dry air 132 and antisolvent vapor 122, through the nozzle 124 and over the perovskite precursor ink 112, thereby quenching 158 the perovskite film 110/710 on substrate 102/702 with the quenching gas mixture 130 for a deposition duration of from about 10 seconds to about 50 seconds, or about 25 seconds. During quenching 158, the selection of the quenching gas mixture 130 deposition duration may be made dependent upon the perovskite precursor ink 112 characteristics. Typically, either antisolvent 120 (e.g. cholorobenzene and similar antisolvents) or gas (e.g. dry air 132) quenching 158 would be applied during a high-speed portion of the spin-coating process to expedite the evaporation of solvents and form the photo-inactive δ phase in perovskite layer 110/710. The disclosed antisolvent-mediated air-quench method 150 advantageously combines both benefits of the air-only 220 and antisolvent-only 210 quenching techniques to provide optimum results through the use of the disclosed nozzle 124 design and antisolvent 120 feed system, as depicted in FIG. 2A and described throughout this disclosure. The disclosed antisolvent-mediated air-quench method 150 provides the benefits of both the ATS quenching method 210 and the gas quenching method 220 during the perovskite layer 110/710 deposition, thereby improving the perovskite film 110/710 properties. The various rates of solvent evaporation directly influence the formation of the perovskite nuclei and subsequently control the transition of the intermediate perovskite phase, i.e., δ-phase, to the photoactive α phase of the perovskite film 110/710 post deposition. Dry air gas 132 (RH about 3%, although other amounts may be possible) may be transported through a container 126, or bath, holding an ATS 120 (such as chlorobenzene, IPA, DEE, toluene and ethanol) for the quench process 158 during spin coating. Moisture present during perovskite film 110/710 formation can lead to perovskite decomposition, while oxygen can oxidize ITO, degrading its conductivity. Thus, the disclosed antisolvent-mediated air-quench method 150 (e.g., providing a quenching gas mixture 130 of dry air 132 and antisolvent vapor 122) reduces environmental sensitivity to the presence of moisture and oxygen during spin coating and perovskite film 110/710 formation. Perovskite films 110/710 formed according to the combined air+CB quench methods 150 comprise a greater proportion of the intermediate perovskite δ-phase after quench 158, as compared to ATS quenching 210 (or CB quenching 210) and air quenching 220, alone, as seen in the schematics of FIGS. 5A-5C.

After the deposition duration from precursor ink deposition 156 and quenching 158, the flow of quenching gas mixture 130 and rotation of chuck 114 is stopped, and the antisolvent-mediated air-quench method 150 further includes annealing 162 the perovskite layer 110/710 on substrate 102/702. The annealing process 162 may be done in an air environment at a first temperature of from 100° C. to 150° C., or about 140° C. for an annealing duration of from about 15 minutes to about 45 minutes, to form a perovskite layer 110/710 comprising all, or substantially all of, the photo active, a perovskite phase. The annealing process 162 serves to impart crystallinity to the as-deposited, quenched 158 perovskite films 110/710, and convert the intermediate and δ-phases present in the post quenched 158 perovskite films 110/710 to the α perovskite phase, present after annealing 162, as shown in the schematics of FIGS. 5D-5F. Perovskite films 110/710 formed by the combinatorial air+CB quenching methods 150 as disclosed herein may comprise a higher proportion of the δ-phase after quenching 158 (as shown in FIG. 5C), leading to conversion of all, or substantially all, of the perovskite film 110/710 to the photo active, a perovskite phase, as shown in the schematics of FIGS. 5D-5F.

A hole transport layer (HTL) 106-706 may be formed 164 over the perovskite layer 110/710 using one or more of: dynamic or static spin coating, sol-gel processing, solution casting, spray coating, dip coating, and combinations thereof. The HTL 106/706 may comprise any of CuSCN, NiOx, Spiro-OMeTAD, Polytriarylamine (PTAA), Poly(3,4-ethylenedioxythiophene), Polystyrene Sulfonate (PEDOT), Graphene Oxide and Reduced Graphene Oxide (rGO), and a substrate or electrode 108/708 may be formed 166 over the HTL 106/706. According to some embodiments, top contacts or electrodes 108/708 may be formed over the HTL 106/706 as carbon based electrodes 708, as depicted in FIG. 7.

The novel manufacturing process and antisolvent-mediated air-quench method 150 as disclosed herein is designed to be compatible with current industrial practices and may be performed under ambient conditions. The use of a quenching gas mixture 130 combination of an antisolvent vapor 122, in this instance CB vapor, and dry air 132 ensures that the perovskite layers 110/710 can be fabricated in an ambient environment preventing damage to the perovskite layers 110/710, resulting in improved perovskite film 110/710 quality and device performance. Perovskite solar cells 100/700 formed according to the antisolvent-mediated air-quench method 150 provide a perovskite layer 110/710 comprising low defect levels, high density and comprise predominately the desired photo-active α perovskite phase. The antisolvent-mediated air-quench method 150, in combination with the custom nozzle 124 design and antisolvent vapor production, maintains the integrity and performance of the entire perovskite solar cell 100/700 structure. By advancing the capabilities of perovskite solar cells 100/700, this disclosure has the potential to significantly reduce the cost per watt of solar energy and accelerate the adoption of solar power on a global scale. The disclosed antisolvent-mediated air-quench method 150 and PSC 100/700 devices formed therefrom provides a scalable and cost-effective pathway for the commercial production of perovskite solar cells 100/700 at large scale production for photovoltaic applications.

This disclosure, its aspects and embodiments, are not limited to the specific material types, components, methods, or other examples disclosed herein. Many additional material types, components, methods, and procedures known in the art are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

In places where the description above refers to particular implementations, it should be readily apparent that several modifications may be made without departing from the spirit thereof and that these implementations may be applied to other implementations disclosed or undisclosed. The presently disclosed inventions are, therefore, to be considered in all respects as illustrative and not restrictive. Many additional implementations are possible. Further implementations are within the CLAIMS.

What is claimed is:

1. A method of making a perovskite solar cell, the method comprising:
disposing a volume of a perovskite precursor ink over a substrate;
disposing a nozzle over the substrate at a distance;
rotating the substrate at a first revolution per minute (RPM) for a first duration;
disposing a gas mixture, comprising dry air and antisolvent vapor, through the nozzle and over the perovskite precursor ink; and
annealing the substrate at a first temperature of from about 100° C. to about 150° C. for an annealing duration of from 5 minutes to 45 minutes to form a perovskite layer comprising a photo active α phase.

2. The method of making a perovskite solar cell of claim 1, wherein disposing the gas mixture comprises displacing ambient air with the dry air and antisolvent vapor gas mixture over a surface of the substrate comprising the perovskite precursor ink.

3. The method of making a perovskite solar cell of claim 1, wherein annealing the substrate fully converts the perovskite layer from an intermediate phase and the δ phase, present after quenching, to the photo active, a phase.

4. The method of making a perovskite solar cell of claim 1, wherein the antisolvent vapor is formed by passing dry air through an antisolvent bath.

5. The method of making a perovskite solar cell of claim 4, wherein the antisolvent bath comprises any of chlorobenzene, IPA, DEE, toluene and ethanol.

6. The method of making a perovskite solar cell of claim 1, wherein the gas mixture comprises the antisolvent vapor in an amount of about 1% to 5%.

7. The method of making a perovskite solar cell of claim 1, wherein disposing the gas mixture, comprising dry air and antisolvent vapor, reduces defects in the perovskite film.

8. The method of making a perovskite solar cell of claim 1, wherein dry air is disposed prior to disposing the gas mixture.

9. A perovskite solar cell comprising:
a transparent conductive oxide (TCO) coated substrate;
an electron transport layer (ETL) disposed over the substrate;
a perovskite photovoltaic layer coupled to the ETL, wherein the perovskite photovoltaic layer comprises all, or substantially all, of the photo active, a perovskite phase;
a hole transport layer (HTL) coupled to the perovskite photovoltaic layer; and
a carbon-based electrode disposed over the HTL.

10. The perovskite solar cell of claim 9, wherein the cell comprises a PCE exceeding 20%.

11. The perovskite solar cell of claim 9, wherein the perovskite solar cell retains about 80% of its initial PCE value after at least 35 hours of exposure at 25° C. and 15% relative humidity.

12. A method of making a perovskite solar cell, the method comprising:
disposing a volume of a perovskite precursor ink over a substrate;
disposing a gas mixture, comprising dry air and antisolvent vapor, over the perovskite precursor ink; and
annealing the substrate at a first temperature for an annealing duration to form a perovskite layer comprising the photo active α phase.

13. The method of making a perovskite solar cell of claim 12, wherein the gas mixture comprises the antisolvent vapor in an amount of about 1% to 5%.

14. The method of making a perovskite solar cell of claim 13, wherein the first temperature is from about 100° C. to about 150° C. and the annealing duration is from 5 minutes to 45 minutes.

15. The method of making a perovskite solar cell of claim 14, wherein the antisolvent vapor is formed by passing dry air through an antisolvent bath.

16. The method of making a perovskite solar cell of claim 15, wherein the antisolvent bath comprises any of chlorobenzene, IPA, DEE, toluene and ethanol.

17. The method of making a perovskite solar cell of claim 12, further comprising:
disposing a nozzle over the substrate at a distance of 10 mm or higher;
rotating the substrate at a first revolution per minute (RPM) of about 1000 RPM to 7000 RPM for a first duration, the first duration lasting 5 to 60 seconds, wherein the gas mixture is disposed at a pressure of at least 20 psi with a flow rate of at least 5 sccm.

18. The method of making a perovskite solar cell of claim 17, wherein disposing the gas mixture while rotating the substrate comprises displacing ambient air with the dry air and antisolvent vapor gas mixture over a surface of the substrate comprising the perovskite precursor ink.

19. The method of making a perovskite solar cell of claim 12, wherein annealing the substrate converts the perovskite layer from an intermediate phase and the δ phase, present after quenching, to the photo active, a phase, with at least 95% converting into the α phase.

20. The method of making a perovskite solar cell of claim 19, wherein dry air is disposed prior to disposing the gas mixture, the dry air having a relative humidity below 5%.
